(19) United States
(12) Patent Application Publication
(10) Pub. No.: US 2007/0246096 A1
(43) Pub. Date: Oct. 25, 2007

(54) Dye-sensitized solar cell

(75) Inventor: Hirokazu Fujimaki, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/703,705

(22) Filed: Feb. 8, 2007

(30) Foreign Application Priority Data
Apr. 20, 2006 (JP) 2006-116318

(51) Int. Cl. H01L 31/042

(52) U.S. Cl. 136/246

(57) ABSTRACT

A dye-sensitized solar cell, comprising: a light-transmission substrate; a plurality of auxiliary electrodes, formed on the light-transmission substrate; an oxide semiconductor layer which is formed on the light-transmission substrate so as to cover the plurality of auxiliary electrodes directly; and dyes, adhered to the oxide semiconductor layer. Each of electrons, excited at the dyes, is transferred to a nearest auxiliary electrode over a distance “C”, which is smaller than a thickness “B” of the oxide semiconductor layer.

### CROSS REFERENCE TO RELATED APPLICATION

This application claims the priority of application No. 2006-116318, filed on Apr. 20, 2006 in Japan, the subject matter of which is incorporated herein by reference.

### TECHNICAL FIELD OF THE INVENTION

The present invention relates to a dye-sensitized solar cell. In particular, the present invention relates to an electrode structure of a dye-sensitized solar cell.

### BACKGROUND OF THE INVENTION

It has been thought that solar energy shining the earth is one hundred of thousand times larger than all electric power consumed in the world. We are surrounded by enormous natural resources. A solar cell or solar battery is a device to convert such natural resources (sunshine) into electric energy, which is easy to use for us human species.

90% of commercial use of solar cells is of a silicon (Si) system solar cell. A silicon system solar cell is categorized by single crystal silicon, polycrystal silicon and amorphous silicon. These types of solar cells are different in conversion efficiency; costs and workability and are selectively used according to mounting device; purpose of use; place for installation. Among Si system solar cells, a single crystal Si solar cell provides the highest conversion efficiency and may achieve to 20% in particular use. Further, for a special use of space satellite or the like, other types of compound semiconductors, having a super high conversion efficiency and a good radiation tolerance performance, may be used.

It has been thought that renewable energy including a solar cell source is almost environmental loading free and is ideal energy source; however, such renewable energy has not been widely used in commercial. One of the major reasons is that a generating cost is high. Under such situation, in order to activate the market of solar cell and to realize an energy supply system (society) harmonized with nature, it is required to reduce a generating cost. In order to reduce a generating cost, there are two technical solutions approaching from the different directions.

First, if conversion efficiency of a solar cell is improved, the total coast including manufacturing cost would be reduced. Second, if material; manufacturing process and structure of the solar cell are improved, unit cost of solar cells could be reduced. For manufacturing a Si system solar sell, which is a mainstream currently, requires a high purity Si material and a high temperature/high vacuum atmosphere. As a result, it is difficult to reduce manufacturing cost. Under such a situation, a variety of other substitute types solar cells have been proposed so as to reduce material cost by using a material other than silicon system; to avoid a high temperature process and a high vacuum process; to reduce energy consumption in manufacturing process; and to reduce total cost of a solar cell consequently. A wet process type of dye-sensitized solar cell (Graetzel Cell) and a dry process type of organic thin film solar cell are proposed instead of a silicon system solar cell.

According to a dye-sensitized solar cell, the cell structure is simple and a great variety of material can be used. Further, it is verified that a generating cost of a dye-sensitized solar cell is one fifth of a Si system solar cell, because a dye- sensitized solar cell is manufactured with low energy consumption and with economical equipments.

Hereinafter, a conventional fabrication process of a dye-sensitized solar cell is described. First, a conductive film, such as FTO and ITO, is coated on a surface of s glass substrate. Next, a paste material, including fine grains of TiO₂, is applied on the surface of the glass substrate by a screen printing process or a printing process.

Next, the Titania paste is sintered by an annealing process, so that organic compound, which is a solvent to the paste, is spattered and necking is occurred to fine grains of titania. As a result, a diffusion path of electrons is formed.

Next, the annealed substrate is dipped in alcohol solvent including Ru (ruthenium) metal complex (for example, N719) for about half a day so that dye of the Ru metal complex is adhered on a surface of the TiO₂ of porous structure. Further, the substrate is washed with alcohol and is dried in a dark place.

Next, as the counter electrode, a thin Pt (platinum) is sputtered on a conductive glass substrate with a pinhole. Himilan films (Trademark Owned by DuPont-Mitsui Polychemicals Co., Ltd.) are formed on peripheral areas of the TiO₂ electrode substrate and the counter electrode substrate, and those two substrates are adhered to each other.

Next, electrolyte including iodine is injected from the pinhole formed on the counter pole (counter electrode) to fill the space between the pair of electrode substrate. After that, the pinhole is covered up.

After that, a minus electrode wiring is connected to the titania electrode, while a plus electrode wiring is connected to the counter pole (counter electrode) to form a flat type of dye-sensitized solar cell.

According to such a dye-sensitized solar cell, when a light comes into the sell from the side where titania is formed, dyes adhered on the surface of the titania absorbs the incident light and electrons are excited. The conduction band of titania has an energy level of about 0.2 eV, which is lower than the excitation level of the dye, so that the excited electrons are transferred toward the titania side. The electrons are transferred through a conductive layer on the glass substrate and operate external load. After that, the electrodes reach the anode side of the cell. Next, reductive reaction of the electrons with iodine ions and the electrons are transferred into the electrolyte. The iodine is diffused and oxidation reaction occurs, so that the electrons are transferred to the excited dyes. Such a process is repeated to generate photo electromotive force based on steady photo irradiation.

According to the above described method of fabrication and mechanism, a dye-sensitized solar cell with high efficiency can be manufactured at a lower cost. A dye-sensitized solar cell can be fabricated in an atmosphere of ordinary pressure and temperature using usual resources, and therefore, a dye-sensitized solar cell can be fabricated at extremely lower costs as compared with a silicon system of solar cell.

According to the below patent publications 1 and 2, in order to decrease the resistance value of electrodes in a dye-sensitized solar cell, an auxiliary electrode having a lower resistance value is formed on a base film and the auxiliary electrode is covered with a transparent layer.

[Patent Publication 1] JP 2005-197176A

[Patent Publication 2] JP 2004-296669A

FIG. 4 shows a conventional dye-sensitized solar cell 10. The dye-sensitized solar cell 10 includes a glass substrate 16; auxiliary electrodes 14, formed on the glass substrate 16; a transparent conductive film 18, formed on the glass substrate 16; and an oxide semiconductor layer (TiO₂) 12 formed so as to cover the auxiliary electrodes 14 and transparent conductive film 18. The transparent conductive film 18 is made of ITO or FTO.

According to the above-described conventional solar cell, when a light passes through the transparent conductive film 18 and the glass substrate 16 and is illuminated to dyes (Ru or the like), adhered on the oxide semiconductor layer 12, electrons (e⁻) would be excited. After that, the excited electrons (e⁻) are transferred through the titania film 12 and transparent conductive film 18 to the auxiliary electrodes 14.

However, according to the above-described conventional solar cell, shown in FIG. 4, the transparent conductive film (ITO or FTO) 18, which is expensive, is used, the total cost of the solar cell would be increased.

Further, when the oxide semiconductor film 12 is annealed at 400° C. to 500° C. to decrease the resistance level of the oxide semiconductor film 12 by increasing the necking (degree of coupling) among particles in the oxide semiconductor film 12, characteristics of the transparent conductive film 18 might be deteriorated (increase of resistance level).

### OBJECTS OF THE INVENTION

Accordingly, an object of the present invention is to provide an advanced dye-sensitized solar cell, which can be fabricated at a lower cost and have a higher efficiency of photoelectric conversion.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a dye-sensitized solar cell, comprising: a light-transmission substrate; a plurality of auxiliary electrodes, formed on the light-transmission substrate; an oxide semiconductor layer which is formed on the light-transmission substrate so as to cover the plurality of auxiliary electrodes directly; and dyes, adhered to the oxide semiconductor layer. Each of electrons, excited at the dyes, is transferred to a nearest auxiliary electrode over a distance “C”, which is smaller than a thickness “B” of the oxide semiconductor layer.

According to a second aspect of the present invention, a dye-sensitized solar cell, comprising: a light-transmission substrate; a plurality of auxiliary electrodes, formed on the light-transmission substrate; an oxide semiconductor layer which is formed on the light-transmission substrate so as to cover the plurality of auxiliary electrodes directly; and dyes, adhered to the oxide semiconductor layer. A distance between a dye, adhered on a surface of the oxide semiconductor layer at the right above the mid point of next two adjacent auxiliary electrodes, and one of the next two adjacent auxiliary electrodes is smaller than a thickness “B” of the oxide semiconductor layer.

As described above, according to the present invention, a transparent conductive film (ITO or FTO), which is expensive, is not used but the auxiliary electrodes are directly covered with a light-absorbing film. As a result, the cost of the solar cell can be decreased.

Electrons excited at dyes, adhered on an oxide semiconductor film, tend to move toward the nearest (closest) conductive material via the shortest route. In the case shown in FIG. 5, the nearest conductive material is an auxiliary electrode 24.

As shown in FIG. 5, if a transparent conductive film (ITO or FTO) is not used but the auxiliary electrodes 24 on the glass substrate 26 are directly covered with the oxide semiconductor film 22, there is a problem regarding a transfer distance of excited electrons in the oxide semiconductor film 22. Now, focusing on an electron (e⁻) which is excited at a location farthest from the nearest auxiliary electrode 24. The location of the electron is where at the right above the mid point of next two adjacent auxiliary electrodes 24, which is indicated by a star symbol. A distance “C” between the location where the electron is excited and the nearest auxiliary electrode 24 is the longest. If such a distance “C” is long, some electrons could not be transferred to any of the auxiliary electrodes 24. As a result, the efficiency of photoelectric conversion could be decreased.

According to the conventional dye-sensitized solar cell, shown in FIG. 4, electrons excited at dyes, adhered on an oxide semiconductor film 12, tend to move toward the nearest (closest) conductive material (auxiliary electrode 14 or transparent conductive film 18) via the shortest route, because the transparent conductive film (ITO or FTO) is used. Even an electron (e⁻) excited at a location farthest from the auxiliary electrodes 14 can reach the transparent conductive film 18 by moving a distance corresponding to a thickness “B” of the oxide semiconductor film 12, which is shorter than distance “C” in FIG. 5.

According to the present invention, each of electrons, excited at the dyes, is transferred to a nearest auxiliary electrode over a distance “C”, which is smaller than a thickness “B” of the oxide semiconductor layer. Alternately, a distance between a dye, adhered on a surface of the oxide semiconductor layer at the right above the mid point of next two adjacent auxiliary electrodes, and one of the next two adjacent auxiliary electrodes is smaller than a thickness “B” of the oxide semiconductor layer. As a result, an electron excited at the right above the mid point of next two adjacent auxiliary electrodes get easily reaches an auxiliary electrode, and therefore, a dye-sensitized solar cell can be fabricated at a lower cost and have a higher efficiency of photoelectric conversion.

### BRIEF DESCRIPTION OF THE DRAWINGS

FIG. 1 is a cross-sectional view illustrating a structure of a dye-sensitized solar cell according to the present invention.

FIG. 2 is a schematic diagram showing an arrangement of anode electrodes of a dye-sensitized solar cell according to a preferred embodiment of the present invention.

FIG. 3 is a schematic diagram showing an arrangement of anode electrodes of a dye-sensitized solar cell according to another preferred embodiment of the present invention.

FIG. 4 is a cross-sectional view illustrating a structure of a conventional dye-sensitized solar cell.

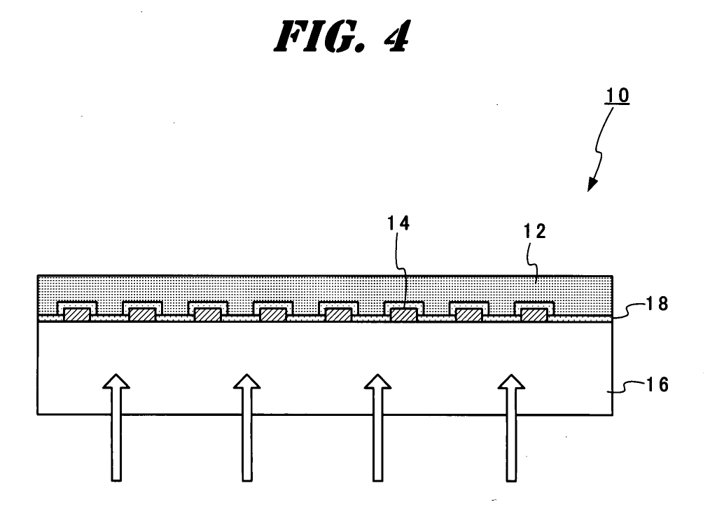

FIG. 5 is a schematic diagram used for describing the principle of the present invention.

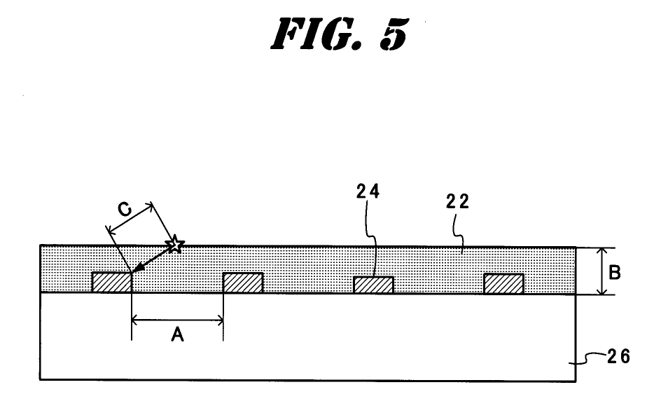

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

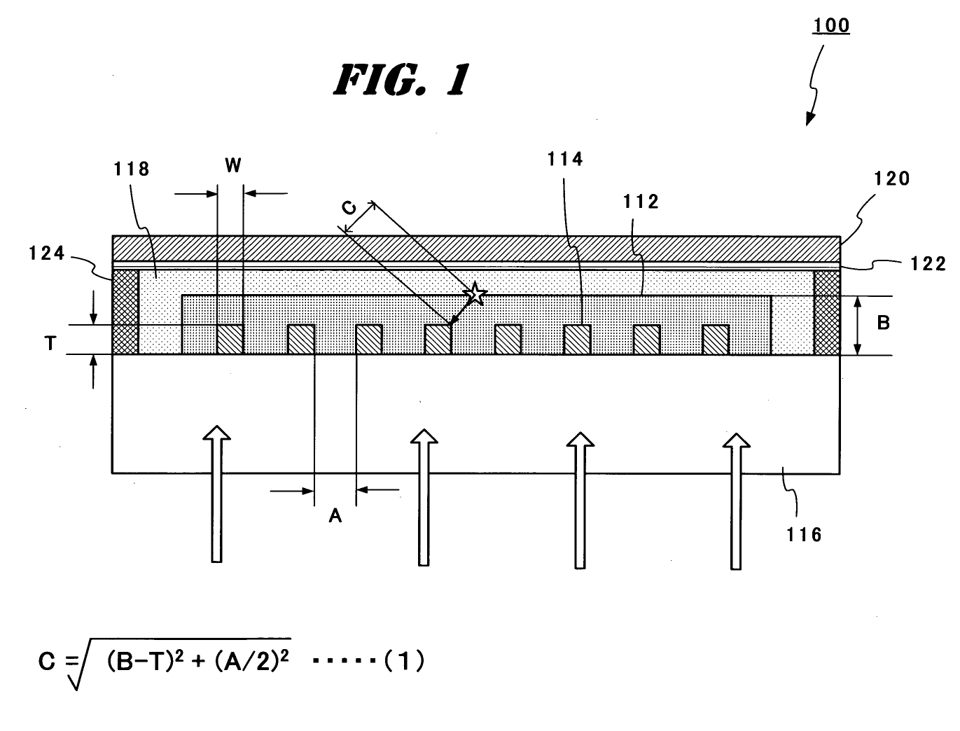

Hereinafter, the present invention is described in reference to an embodiment. FIG. 1 is a cross-sectional view illustrating a structure of a dye-sensitized solar cell 100 according to the present invention. The dye-sensitized solar cell 100 includes a translucent glass substrate 116; auxiliary electrodes 14, formed on the glass substrate 116; an oxide semiconductor layer (Titania: TiO₂) 112 formed so as to cover the auxiliary electrodes 114 directly; an electrolytic solution (iodine) 118, filled at the peripheral of the oxide semiconductor layer 112; a sealing member 124 which seals the electrolytic solution 118; and a metal plate (cathode electrode) 120 having a surface coated with a Pt coating layer 122. Dyes, such as ruthenium (Ru) are adhered on a surface of the oxide semiconductor layer 112.

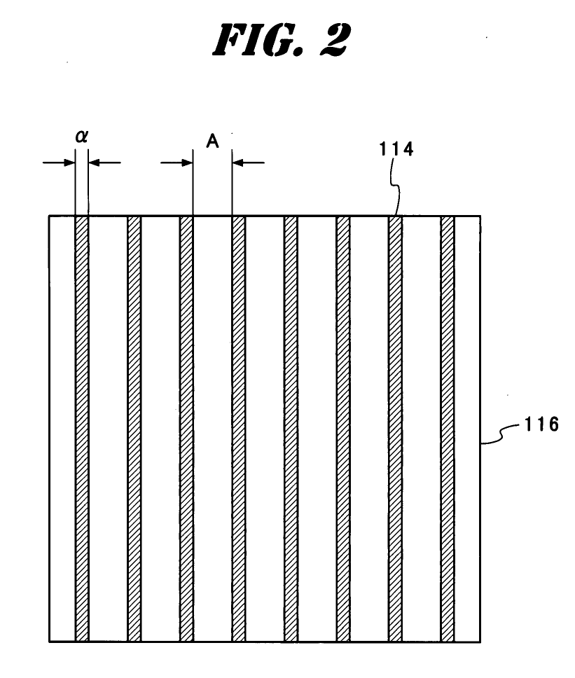

Next, a method for fabricating the dye-sensitized solar cell 100 is described. First, a tungsten film is formed to have a thickness of 3 μm by a sputtering process, CVD process or vacuum evaporation method. Next, the tungsten film is shaped stripes, as shown in FIG. 2, to form auxiliary electrodes (anode electrodes) 114. The electrodes 114 are shaped to have a thickness “T” of 4 μm and have a distance (gap) “A” between adjacent (next) two electrodes of 15 μm.

Next, dispersing liquid, including TiO₂ fine grains (minute particles) having a diameter of about 20 nm to 30 nm, is coated on the glass substrate 116 to have a thickness of about 50 μm. After that, the glass substrate 116 is annealed at about 450° for about two hours to form an oxide semiconductor layer (Titania layer), having a thickness of about 10 μm to 20 μm. During the annealing process, organic substance (polyethylene glycol) is spattered and necking is occurred to form a diffusion path of electrons. As a result, a porous titania film (oxide semiconductor layer) 112 is formed to cover the auxiliary electrodes 114 directly.

Next, the annealed substrate is dipped in alcohol solvent including Ru (ruthenium) metal complex (for example, N719) for about half a day so that dye of the Ru metal complex is adhered on a surface of the TiO₂ of porous structure. Further, the substrate is washed with alcohol and is dried in a dark place.

Next, the annealed substrate is dipped in alcohol solvent including Ru (ruthenium) metal complex (for example, N719) for about half a day so that dye of the Ru metal complex is adhered on a surface and inside of the TiO₂ of porous structure. As dyes to be adhered to the porous titania film 112, N3 dye, N719 dye and black dye can be used.

Next, the substrate is washed with alcohol and is dried in a dark place. After that, the glass substrate 116 with a pinhole and a metal plate (cathode electrode) 120, in which a thin Pt (platinum) coating 122 is formed on a surface thereof, are adhered to each other using a seal material 124. As the seal material 124, for example, photo-curing (photo-setting) type of liquid state seal material (31X-101 by Three Bond Ltd.) can be used.

Next, electrolyte 118, including iodine, is injected from the pinhole formed in the glass substrate 116 to fill the space between the pair of electrodes (anode and cathode). After that, the pinhole is covered up. Subsequently, a minus electrode wiring is connected to the auxiliary electrodes 114, while a plus electrode wiring is connected to the cathode electrode plate 120 to form a dye-sensitized solar cell.

According to the dye-sensitized solar cell 100, when a light comes into the sell from the side of the glass substrate 116, dyes adhered on the surface of the oxide semiconductor substrate (titania film) 112 absorbs the incident light and electrons are excited. The excited electrons are transferred to the auxiliary electrodes 114, and reach the anode side (120) of the cell. After that, reductive reaction of the electrons with iodine ions and the electrons are transferred into the electrolyte 118. The iodine is diffused and oxidation reaction occurs, so that the electrons are transferred to the excited dyes. Such a process is repeated to generate photo electromotive force based on steady photo irradiation.

It is important to determine dimensions of According to the dye-sensitized solar cell 100, each of electrons, excited at the dyes, is transferred to the nearest auxiliary electrode 14 over a distance “C”, which is smaller than a thickness “B” of the oxide semiconductor layer 112.

In other words, a distance between a dye, adhered on a surface of the oxide semiconductor layer 112 at the right above the mid point of next two adjacent auxiliary electrodes 114, and one of the next two adjacent auxiliary electrodes 114 is smaller than a thickness “B” of the oxide semiconductor layer 112. The distance “C” is calculated by the formula (1), shown in FIG. 1, where a thickness of the auxiliary electrodes 114 is “T”, a distance between next two auxiliary electrodes 114 is “A” and a thickness of the oxide semiconductor substrate (titania film) 112 is “B”.

According to the present invention, an electron (e⁻) excited at a location farthest from the auxiliary electrodes 114, which is indicated by a star symbol, can reach an auxiliary electrode 114 easily. As a result, an advanced dye-sensitized solar cell, which can be fabricated at a lower cost and have a higher efficiency of photoelectric conversion, is provided.

In general, in order to decrease a resistance level of the auxiliary electrode 114, a cross-sectional area (W×T) should be increased. However, if a width W of the auxiliary electrode 114 is increased, a distance (interval) A between next two electrodes 114 would be decreased, namely, an entrance window for lights would get smaller. As a result, an efficiency of photoelectric conversion would be decreased. In order to avoid the entrance window of lights from being become smaller in area and at the same time to increase the cross-sectional area of the auxiliary electrodes 114, according to the present invention, preferably, the auxiliary electrodes 114 are designed to meet a condition of “T/W>1”. In other words, preferably, the thickness “T” is larger than the width “W”.

For example, it is assumed that there are two designs (1) and (2) of the auxiliary electrodes 114. According to design (1), each of the auxiliary electrodes 114 is formed to have a width of 1 μm and a thickness of 0.5 μm. According to design (2), each of the auxiliary electrodes 114 is formed to have a width of 0.5 μm and a thickness of 1.0 μm. The cross-sectional areas of the auxiliary electrode 114 are identical between designs (1) and (2). However, according to the design (2), a distance between next two auxiliary electrodes 114 can be designed larger, so that an entrance window for lights (numerical aperture) gets larger as compared with the design (1). That is, if the auxiliary electrodes 114 are designed to meet a condition of “T/W>1”, the amount of lights entered in the electrodes 114 would be increased and the resistance level of the electrodes 114 would be decreased. As a result, a high efficiency of photoelectric conversion can be provided.

FIG. 2 is a schematic diagram showing an arrangement of anode electrodes (auxiliary electrodes) 114 of a dye-sensitized solar cell 100 according to a preferred embodiment of the present invention. According to the embodiment, shown in FIG. 2, the auxiliary electrodes 114 are shaped in stripe (narrow straight) and are arranged parallel to each other. According to the design, shown in FIG. 2, a surface area of a dye adhering layer, such as titania film, is increased, and therefore, an efficiency of photoelectric conversion is improved.

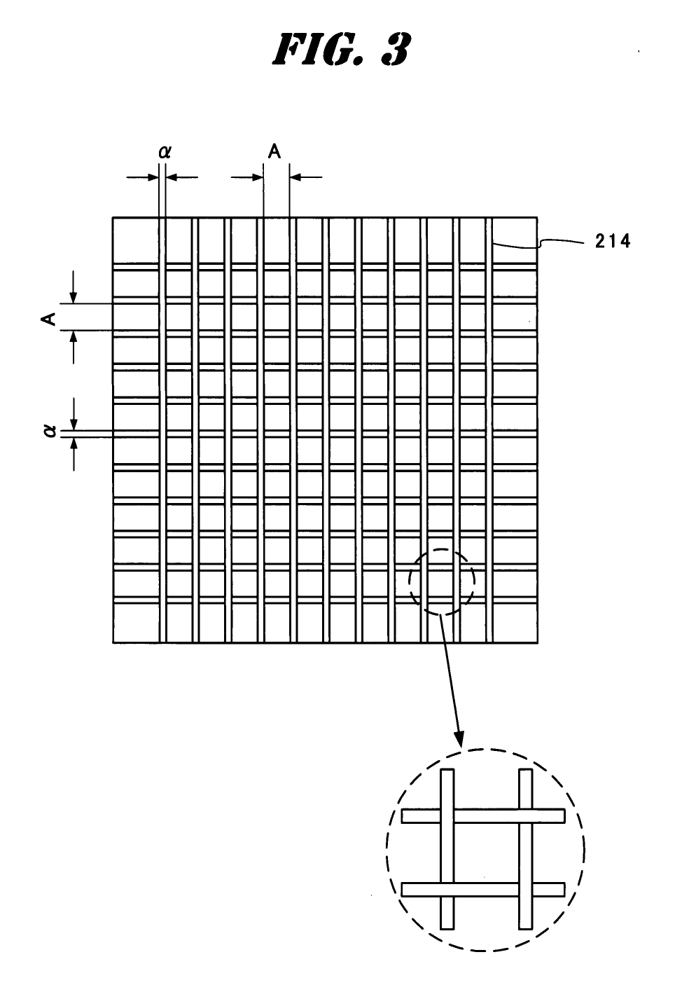

FIG. 3 is a schematic diagram showing an arrangement (shape) of anode electrode (auxiliary electrode) of a dye-sensitized solar cell 100 according to another preferred embodiment of the present invention. According to the embodiment, shown in FIG. 3, anode electrode 214 is shaped in reticulated or mesh manner. When the anode electrode 214 is made of aluminum, a plurality of aluminum wires are arranged in matrix, including horizontal and vertical wires, on a glass substrate, and the wires are heated (melted) to form a mesh-shape of electrode. After that, a titan layer is formed on the mesh-shaped electrode 214 by a sputtering process to have a thickness of about 100 Å, and the titan layer is oxidized. Alternately, an oxide titan layer is formed on the mesh-shaped electrode 214 by a sputtering process to have a thickness of about 100 Å. In either way, the mesh-shaped electrode 214 is covered with an oxide titan layer.

According to the present embodiment, shown in FIG. 3, the anode electrode layer 214 is mesh-shaped, a higher efficiency of photoelectric conversion can be provided as compared with the embodiment, shown in FIG. 2. That is because; electric current is allowed to flow not only in one direction but over the network of tungsten wires entirely, and therefore, an inner electrical resistance (anode resistance) is remarkably reduced. In FIG. 3, the anode electrode 214 is shaped as a square mesh pattern, having quadrilateral gaps regularly. However, an inhomogeneous pattern can be used as long as a two-dimensional current path is formed.

An auxiliary electrode may be made of material including at least one kind of a high corrosion-resistance material, such as titan (Ti), nickel (Ni) or the like, instead of tungsten. When an auxiliary electrode 114 is made of aluminum (Al), a surface of the Al electrode is covered with a tungsten film, titan film or nickel film in order to prevent from corrosion with electrolytic solution (iodine). Since aluminum (Al) has a lower resistance level, an auxiliary electrode of aluminum further improves an efficiency of photoelectric conversion. In the case that a surface of an aluminum electrode is covered with a titan film, the titan film should be oxidized entirely.

As a transparent substrate (light transmission substrate) 116, a plastic film can be used instead of a glass substrate. If a plastic film is used as a transparent substrate (light transmission substrate) 116, it is preferable to coat a high corrosion-resistance material on a surface of the plastic film to prevent from corrosion with electrolytic solution (iodine).

A cathode metal plate 120 may be made of Cu, SUS, W or Al, and is covered (coated) with a catalytic material, such as platinum (Pt) or carbon (C). As a catalytic material (reducing iodine ions), a platinum chloride or PEDOT (Poly (3,4-ethylenedioxythiophene)) may be used.

What is claimed is:

1. A dye-sensitized solar cell, comprising:
a light-transmission substrate;
a plurality of auxiliary electrodes, formed on the light-transmission substrate;
an oxide semiconductor layer which is formed on the light-transmission substrate so as to cover the plurality of auxiliary electrodes directly; and
dyes, adhered to the oxide semiconductor layer, wherein each of electrons, excited at the dyes, is transferred to a nearest auxiliary electrode over a distance “C”, which is smaller than a thickness “B” of the oxide semiconductor layer.

2. A dye-sensitized solar cell according to claim 1, wherein
a horizontal width “W” of the auxiliary electrode is smaller than a thickness “T” of the auxiliary electrode.

3. A dye-sensitized solar cell according to claim 1, wherein
the oxide semiconductor layer is of a titania layer.

4. A dye-sensitized solar cell according to claim 1, wherein
the dye is formed to include ruthenium (Ru).

5. A dye-sensitized solar cell according to claim 1, wherein
the dye is formed to include indium (In).

6. A dye-sensitized solar cell according to claim 1, wherein
the auxiliary electrode is formed to include tungsten.

7. A dye-sensitized solar cell according to claim 1, wherein
the plurality of auxiliary electrodes is arranged to be parallel to each other.

8. A dye-sensitized solar cell according to claim 1, wherein
the plurality of auxiliary electrodes is arranged in reticulated or mesh manner.

9. A dye-sensitized solar cell, comprising:
a light-transmission substrate;
a plurality of auxiliary electrodes, formed on the light-transmission substrate;
an oxide semiconductor layer which is formed on the light-transmission substrate so as to cover the plurality of auxiliary electrodes directly; and
dyes, adhered to the oxide semiconductor layer, wherein
a distance between a dye, adhered on a surface of the oxide semiconductor layer at the right above the mid point of next two adjacent auxiliary electrodes, and one of the next two adjacent auxiliary electrodes is smaller than a thickness “B” of the oxide semiconductor layer.

10. A dye-sensitized solar cell according to claim 9, wherein
a horizontal width “W” of the auxiliary electrode is smaller than a thickness “T” of the auxiliary electrode.

11. A dye-sensitized solar cell according to claim 9, wherein
the oxide semiconductor layer is of a titania layer.

12. A dye-sensitized solar cell according to claim 9, wherein
the dye is formed to include ruthenium (Ru).

13. A dye-sensitized solar cell according to claim 9, wherein
the dye is formed to include indium (In).

14. A dye-sensitized solar cell according to claim 9, wherein
the auxiliary electrode is formed to include tungsten.

15. A dye-sensitized solar cell according to claim 9, wherein
the plurality of auxiliary electrodes is arranged to be parallel to each other.

16. A dye-sensitized solar cell according to claim 9, wherein
the plurality of auxiliary electrodes is arranged in reticulated or mesh manner.
